(19) United States
(12) Patent Application Publication
(10) Pub. No.: US 2024/0040788 A1
(43) Pub. Date: Feb. 1, 2024

(54) NONVOLATILE MEMORY DEVICE AND MANUFACTURING METHOD THEREFOR

(71) Applicants: NATIONAL INSTITUTE OF ADVANCED INDUSTRIAL SCIENCE AND TECHNOLOGY, Tokyo (JP); ULVAC, INC., Kanagawa (JP)

(72) Inventors: Noriyuki Miyata, Ibaraki (JP); Shutaro Asanuma, Ibaraki (JP); Kyoko Sumita, Ibaraki (JP); Yuusuke Miyaguchi, Kanagawa (JP); Kazuya Saito, Kanagawa (JP); Takehito Jinbo, Kanagawa (JP); Kazumasa Horita, Kanagawa (JP); Takeshi Masuda, Kanagawa (JP)

(21) Appl. No.: 18/265,250

(22) PCT Filed: Oct. 15, 2021
(86) PCT No.: PCT/JP2021/038188

§ 371 Date: Jun. 3, 2023

(30) Foreign Application Priority Data
Dec. 3, 2020 (JP) 2020-201236

(51) Int. Cl. H10B 43/35; H10B 43/23; H10B 41/23; H10B 41/35

(52) U.S. Cl. CPC H10B 43/35; H10B 43/23; H10B 41/23; H10B 41/35

(57) ABSTRACT

[PROBLEM] An object of the present invention is to provide a nonvolatile memory device having an excellent information retention characteristic, exhibiting high performance, and achieving practical mass-production, and a manufacturing method therefor.

[SOLUTION] A nonvolatile memory device 1 has a laminated structure part including a plurality of Al₂O₃ layers 4 and a plurality of SiO₂ layers 6 formed as two types of insulating layers formed with different compositions and disposed alternately, and an O-M₁-O layer 5 of a 0.5 molecular layer to a 2.0 molecular layer, formed by a chemical bond between a metal element M₁ and oxygen, and disposed on each joining interface between the insulating layers, the metal element M₁ being an element other than elements constituting the insulating layers, and the nonvolatile memory device stores information by modulating an interface dipole induced in the vicinity of the O-M₁-O layer 5 by external electrical stimulation.

### TECHNICAL FIELD

The present invention relates to a nonvolatile memory device having a modulation structure of an interface dipole induced between aluminum oxide and silicon oxide and a manufacturing method therefor.

### BACKGROUND ART

The market of semiconductor storage devices using an NAND flash memory as information storage devices incorporated in information appliances such as a portable terminal expands. The NAND flash memory is an element having features of high integration, large capacity, and nonvolatile information storage, and currently, research and development to achieve high capacity and high performance mainly by microprocessing and a three-dimensional structure technology are promoted.

The microprocessing approaches criteria of stable machining by the physical limitation on the principle of operation, and further, the three-dimensional structure technology has many problems, so that it is difficult to expect that large capacity and high performance of the NAND flash memory are continuously enhanced in future. Particularly, the NAND flash memory has demerits that rewriting durability is low, and further, reading speed and writing speed are slow.

In order to overcome these demerits, the inventors of the present invention have proposed a first nonvolatile memory device using interface dipole modulation (see Patent Document 1). According to this proposal, high-performance memory operations exceeding the performance of the NAND flash memory can be expected without making a large change to a MOS structure and constituents in the NAND flash memory or the like.

However, the first nonvolatile device has a metal-oxide layer/semiconductor interface structure, and a metal element for an operation of interface dipole modulation is placed close to the surface of the semiconductor, and therefore, in a case where a transistor structure is applied, an electric characteristic might be deteriorated by an increase of interface state density in an insulating layer/semiconductor structure.

In view of this, the inventors have further proposed a second nonvolatile memory device obtained by improving the first nonvolatile memory device (see Patent Document 2). In the second nonvolatile memory device, instead of the interface dipole modulation operation in the metal-oxide layer/semiconductor structure in the first nonvolatile memory device, an O-M₁-O layer (an interface dipole modulation layer) is disposed on an interface between two different types of insulating layers, and strength or polarity of the interface dipole induced in the vicinity of the O-M₁-O layer is changed so as to solve a problem related to the interface state density of the first nonvolatile memory device.

More specifically, an HfO₂ layer (the aforementioned insulating layer) is deposited by an electron beam evaporation method, an O-M₁-O layer equivalent to a monolayer is then deposited on this layer by the electron beam evaporation method, an SiO₂ layer (the aforementioned insulating layer) is then deposited by the electron beam evaporation method, defects in the HfO₂ layer and the SiO₂ layer are reduced by heating at 450° C., and thus, the interface dipole modulation structure in the second nonvolatile memory device is formed (see Examples 1 and 2 in Patent Document 2). Note that the electron beam evaporation method is a deposition method of forming a film with a small area while a minute film is provided.

However, in further studies, it has become clear that the second nonvolatile memory device having the interface dipole modulation structure with the HfO₂ layer, the O-M₁-O layer, and the SiO₂ layer has the following two problems.

First, the retention time of stored information in the second nonvolatile memory device is short, and the second nonvolatile memory device has a problem in performance (see Non Patent Document 1).

Second, at the time when the manufacture using an ALD (Atomic Layer Deposition) method that can form a film with a large area at a time is performed, when a post heat treatment is performed at 400° C. or more after deposition by the ALD method, such a problem occurs that a memory characteristic is impaired due to a low heat resistance (see Non Patent Document 2). In the manufacturing process using the ALD method, the high-temperature heat treatment after the deposition is a necessary treatment to obtain a desired film, and therefore, the low heat resistance means that it is very difficult to achieve mass-production by a practical manufacturing method.

### PRIOR ART DOCUMENTS

### Patent Documents

Patent Document 1: Japanese Patent No. 6145756 Patent Document: Japanese Patent No. 6472149

### Non Patent Documents

Non Patent Document 1: N. Miyata, Sci. Rep. 8, 8486 (2018)
Non Patent Document 2: S. Asanuma, K. Sumita, Y. Miyaguchi, K. Horita, T. Jimbo, K. Saito, and N. Miyata, AIP Adv. 10, 085114 (2020)

### DISCLOSURE OF THE INVENTION

### Problems to be Solved by the Invention

The present invention is to solve the problems in the related art and to achieve the following object. That is, an object of the present invention is to provide a nonvolatile memory device having an excellent information retention characteristic, exhibiting high performance, and achieving practical mass-production, and a manufacturing method therefor.

The inventors have investigated diligently to solve the problems and obtained the following findings.

That is, after a trial and error, the inventors found that, when an interface dipole modulation structure with an Al₂O₃ layer, the O-M₁-O layer, and the SiO₂ layer is formed instead of the interface dipole modulation structure with the HfO₂ layer, the O-M₁-O layer, and the SiO₂ layer, the memory characteristic by the interface dipole modulation structure is not impaired even when the high-temperature heat treatment is performed after the deposition by the ALD method. Further, as a result of examination of the information retention characteristic of the nonvolatile memory device having the interface dipole modulation structure with the Al₂O₃ layer, the O-M₁-O layer, and the SiO₂ layer, the inventors surprisingly found that the stored information thereof can be held longer than the interface dipole modulation structure with the HfO₂ layer, the O-M₁-O layer, and the SiO₂ layer.

Patent Document 2 deals with Al₂O₃ as a formation material for one of the two different types of insulating layers, but Patent Document 2 does not examine anything about the use of the Al₂O₃ layer and the SiO₂ layer as the combination of formation materials of the two types of insulating layers, and further, Patent Document 2 does not examine anything about the information retention characteristic and the heat resistance in the case of using the Al₂O₃ layer and the SiO₂ layer.

The findings obtained this time result in extensive contribution to the practical use of the nonvolatile memory device using the interface dipole modulation.

### Means for Solving the Problems

The present invention is based on the findings and the means for solving the problems is as follows.

<1> A nonvolatile memory device having a laminated structure part including a plurality of first insulating layers and a plurality of second insulating layers formed with different compositions and disposed alternately, and an O-M₁-O layer of a 0.5 molecular layer to a 2.0 molecular layer formed by a chemical bond between a metal element M₁ and oxygen, and disposed on a joining interface between each of the first insulating layers and a corresponding one of the second insulating layers, the metal element M₁ being an element other than elements constituting the first insulating layers and the second insulating layers, and information being stored by modulating an interface dipole induced in the vicinity of the O-M₁-O layer due to external electrical stimulation, wherein the first insulating layers are formed of aluminum oxide and the second insulating layers are formed of silicon oxide.

<2> The nonvolatile memory device according to <1>, wherein the first insulating layers have a thickness of 2 nm or less.

<3> The nonvolatile memory device of <1> or <2>, wherein the second insulating layers have a thickness of 2 nm or less.

<4> The nonvolatile memory device according to any one of <1> to <3>, wherein the metal element M₁ is Ti.

<5> The nonvolatile memory device according to any one of <1> to <4>, wherein the number of O-M₁-O layers with a modulable interface dipole is six or more.

<6> The nonvolatile memory device according to any one of <1> to <5>, wherein a silicon semiconductor substrate and a silicon oxide underlayer laminated on a surface of the silicon semiconductor substrate are disposed and the first insulating layer of the laminated structure part is laminated on the silicon oxide underlayer.

<7> The nonvolatile memory device according to <6>, wherein an outermost surface of the laminated structure part is the second insulating layer with a surface of the first insulating layer side laminated on the silicone oxide underlayer being taken as a bottom surface, and an O-M₁-O layer, an aluminum oxide metal electrode underlayer, and a metal electrode are laminated on the outermost surface in this order.

<8> The nonvolatile memory device according to <7>, wherein the silicon semiconductor substrate includes a semiconductor region of a first conductive type, and a source region and a drain region of a second conductivity type, the source region and the drain region being disposed to be distanced from each other in a state where the source region and the drain region are partially exposed from a surface of the silicon semiconductor substrate and strength or polarity of the interface dipole induced in the vicinity of the O-M₁-O layer is changed by an electrical signal applied to the metal electrode.

<9> A manufacturing method for the nonvolatile memory device according to any one of <1> to <8>, including: a deposition step of depositing and forming by an ALD method each constituent layer of a laminated structure part constituted by a first insulating layer, an O-M₁-O layer and a second insulating layer, and a post heating step of heating the laminated structure part at a temperature of 250° C. or more after the deposition step.

### Effect of the Invention

According to the present invention, it is possible to solve the problems in the prior art and to provide a nonvolatile memory device having an excellent information retention characteristic, exhibiting high performance, and achieving practical mass-production, and a manufacturing method therefor.

### BRIEF DESCRIPTION OF THE DRAWINGS

FIG. 1 is a sectional structural drawing according to a first embodiment of the nonvolatile memory device according to the present invention.

FIG. 2 is a sectional structural drawing according to a second embodiment of the nonvolatile memory device according to the present invention.

FIG. 3 is a view illustrating a measurement result of a capacity-voltage characteristic (a C-V characteristic) of the nonvolatile memory device according to Example 1.

FIG. 4 is a view illustrating a measurement result of a capacity-voltage characteristic (a C-V characteristic) of the nonvolatile memory device according to Comparative Example 1.

FIG. 5 is a view illustrating a measurement result of an information retention characteristic of the nonvolatile memory device according to Example 1.

FIG. 6 is a view illustrating a measurement result of an information retention characteristic of the nonvolatile memory device according to Comparative Example 4.

FIG. 7 is a view illustrating the relationship between a hysteresis characteristic and a heat-treatment temperature characteristic in the nonvolatile memory device according to each of Examples 1 to 5.

FIG. 8 is a view illustrating the relationship between a hysteresis characteristic and a heat-treatment temperature characteristic in the nonvolatile memory device according to each of Comparative Examples 1 to 5.

FIG. 9 is a view illustrating Al₂O₃/SiO₂ thickness dependency of a hysteresis voltage.

### MODE FOR CARRYING OUT THE INVENTION

### First Embodiment

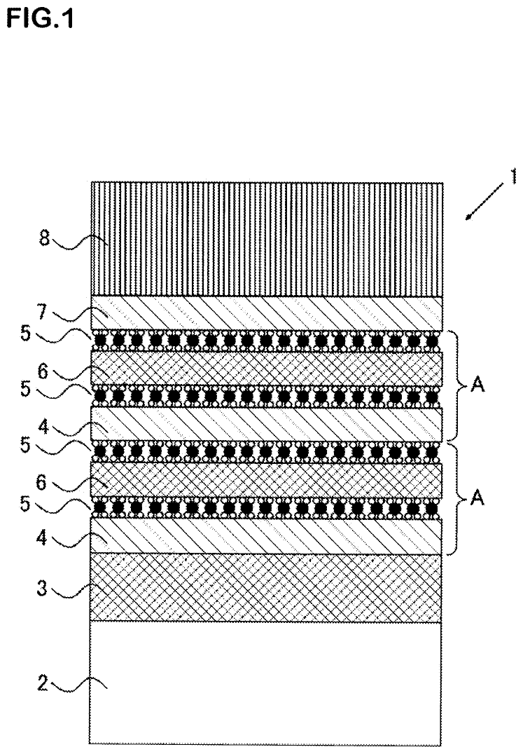

FIG. 1 is a sectional structural drawing according to the first embodiment of the nonvolatile memory device according to the present invention.

As illustrated in FIG. 1, the nonvolatile memory device 1 according to the first embodiment is constituted by a silicon semiconductor substrate 2, a silicon oxide underlayer 3 (hereinafter referred to as an SiO₂ underlayer 3), an aluminum oxide layer 4 (hereinafter referred to as an Al₂O₃ layer 4) as a first insulating layer, an O-M₁-O layer 5, a silicon oxide layer 6 (hereinafter referred to as an SiO₂ layer 6) as a second insulating layer, an aluminum oxide metal electrode underlayer 7 (hereinafter referred to as an Al₂O₃ metal electrode underlayer 7), and a metal electrode 8.

A plurality (two) of Al₂O₃ layers 4 and a plurality (two) of SiO₂ layers 6 formed of different compositions are disposed alternately, and the O-M₁-O layer 5 formed by a chemical bond between a metal element M₁ and oxygen is disposed on a joining interface therebetween, the metal element M₁ being an element other than elements constituting the Al₂O₃ layer 4 and the SiO₂ layer 6.

A technical main point of the nonvolatile memory device according to the present invention is that two types of insulating layers formed of different compositions are constituted by the Al₂O₃ layer 4 and the SiO₂ layer 6.

With such a configuration, it is possible to obtain a long-term information retention characteristic and an excellent heat resistance. The excellent heat resistance provides durability to a post heat treatment at high temperature to be performed after deposition by the ALD method and enables a practical mass-productive method of the nonvolatile memory device by use of the ALD method.

A laminated structure part constituted by the Al₂O₃ layers 4, the O-M₁-O layers 5, and the SiO₂ layers 6 enables modulation of interface dipoles induced in the vicinity of the O-M₁-O layers 5 by external electrical stimulation.

The interface dipole means a potential difference between the Al₂O₃ layer 4 and the SiO₂ layer 6.

While aluminum oxide (Al₂O₃) having a large permittivity causes small potential fluctuation by Al atoms having a positive charge and O atoms having a negative charge, silicon oxide (SiO₂) having a small permittivity causes large potential fluctuation by Si atoms having a positive charge and O atoms having a negative charge. As a result, the interface dipole is induced between the Al₂O₃ layer 4 and the SiO₂ layer 6.

Further, at this time, the Al₂O₃ layers 4 and the SiO₂ layers 6 are disposed alternately, so that two O-M₁-O layers 5 are formed on two types of opposed interfaces of Al₂O₃/SiO₂ and SiO₂/Al₂O₃ with intermediate SiO₂ being shared, and hereby, a potential difference caused between upper Al₂O₃ and lower Al₂O₃ can be made larger than that of a configuration in which one O-M₁-O layer 5 is disposed on an Al₂O₃/SiO₂ interface.

The interface dipole is modulable by changing the positions of O atoms and M₁ atoms in the vicinity of the joining interface by external electrical stimulation, and the nonvolatile memory device 1 controls the external electrical stimulation to perform a nonvolatile information storage operation using the modulation phenomenon of the interface dipole.

The interface dipole modulation can be observed as hysteresis voltage in a capacity-voltage characteristic when the external electrical stimulation is applied, and an excellent information storage characteristic with a larger modulation width is obtained as the hysteresis voltage becomes larger.

From the viewpoint of obtaining a large hysteresis voltage, the Al₂O₃ layer 4 preferably has a thickness of 2 nm or less and particularly preferably has a thickness of 1 nm or less.

Further, from the viewpoint of obtaining a large hysteresis voltage, the SiO₂ layer 6 also preferably has a thickness of 2 nm or less and particularly preferably has a thickness of 1 nm or less.

The thicknesses of the Al₂O₃ layer 4 and the SiO₂ layer 6 have no lower limit particularly and correspond to the thickness of a monomolecular layer.

The O-M₁-O layer 5 has a thickness equivalent to the thickness of a 1 molecular layer to a 2 molecular layer, and the O-M₁-O layer 5 is disposed on the joining interface as a 0.5 molecular layer to a 2.0 molecular layer by multiplying the thickness by a coverage factor (1.0 or less) to a forming surface.

The metal element M₁ may be, for example, one or more elements selected from the group consisting of magnesium, titanium, strontium, yttrium, lantern, tantalum, gallium, and antimony, but most especially, titanium is preferable.

Further, in the embodiment illustrated in FIG. 1, 4 layers of the O-M₁-O layers 5 are provided, but as the number of the O-M₁-O layers 5, the interface dipole of which is modulable, is larger, a larger hysteresis voltage is easily obtainable, and therefore, the number of the O-M₁-O layers 5 is preferably 6 or more, more preferably 8 or more, and particularly preferably 12 or more. Note that the upper limit of the number of the layers is around 20 from the viewpoint of required performance and easy manufacture.

A formation method for each constituent layer of the laminated structure part constituted by the Al₂O₃ layer 4, the O-M₁-O layer 5, and the SiO₂ layer 6 is preferably a formation method including a deposition step by the ALD method, and a post heating step of performing heating at a temperature of 250° C. or more after the deposition step, as a post heat treatment for excellent film formation. The deposition step and the post heating step can be performed by a well-known ALD device, a well-known heating device, and so on.

The ALD method can perform deposition with a large area at a time, and therefore, with this formation method, the nonvolatile memory device 1 can be mass-produced practically.

There is no particular limit for the heating temperature in the post heating step, provided that the heating temperature is 250° C. at lowest, but from the viewpoint of obtaining a finer structure, the heating temperature is preferably 350° C. or more and particularly preferably 450° C. or more. Note that the upper limit of the heating temperature is around 600° C.

In the embodiment of the nonvolatile memory device 1, the SiO₂ underlayer 3 laminated on the surface of the silicon semiconductor substrate 2 is disposed. This structure can be formed by thermal oxidization of the surface layer of a well-known silicon semiconductor substrate, and hereby, an insulating layer/semiconductor structure having a low interface state density is obtained.

Further, in the embodiment of the nonvolatile memory device 1, the outermost surface of the laminated structure part is the SiO₂ layer 6 with a surface of the Al₂O₃ layer 4 side laminated on the SiO₂ underlayer 3 being taken as a bottom surface, and the O-M₁-O layer 5, the Al₂O₃ metal electrode underlayer 7, and the metal electrode 8 are laminated on the outermost surface in this order.

The joining interface between the SiO₂ layer 6 as the outermost surface of the laminated structure part and the Al₂O₃ metal electrode underlayer 7 includes the O-M₁-O layer 5 similarly to the joining interface between the SiO₂ layer 6 and the Al₂O₃ layer 4, so that the interface dipole can be induced in the vicinity of the O-M₁-O layer 5 in the joining interface of SiO₂/Al₂O₃, and in this sense, the structure of the SiO₂ layer 6 on the outermost surface, the O-M₁-O layer 5, and the Al₂O₃ metal electrode underlayer 7 has a role common with the laminated structure part. The expression of the number of the O-M₁-O layers 5, the interface dipole of which is modulable, also includes the O-M₁-O layer 5 disposed on the joining interface between the SiO₂ layer 6 and the Al₂O₃ metal electrode underlayer 7.

Note that, differently from the Al₂O₃ layer 4, the Al₂O₃ metal electrode underlayer 7 has a role as the underlayer for the metal electrode 8 and has a thickness set independently from the Al₂O₃ layer 4.

The thickness of the Al₂O₃ metal electrode underlayer 7 is preferably 1 nm to 5 nm. When the thickness is less than 1 nm, a modulation action may not be caused in this layer, and when the thickness exceeds 5 nm, a high voltage may be required to obtain a modulation action.

Note that the Al₂O₃ metal electrode underlayer 7 can be formed by the same formation method as the Al₂O₃ layer 4.

Further, the metal electrode 8 can be formed by a well-known formation method such as an electron beam evaporation method, a vacuum evaporation method, or spattering method by use of a well-known electrode material such as iridium, gold, aluminum, or titanium nitride as a formation material.

Further, instead of the embodiment of the nonvolatile memory device 1, the nonvolatile memory device according to the present invention may be configured to include the O-M₁-O layer 5 between the SiO₂ underlayer 3 and the Al₂O₃ layer 4 laminated on the SiO₂ underlayer 3, as a modification. The interface dipole of the O-M₁-O layer 5 between the SiO₂ underlayer 3 and the Al₂O₃ layer 4 in this modification is also modulable, and therefore, the O-M₁-O layer 5 is counted at the number of the O-M₁-O layers 5, the interface dipole of which is modulable, and is also advantageous to obtain a large hysteresis voltage. In this case, the O-M₁-O layer 5 between the SiO₂ underlayer 3 and the Al₂O₃ layer 4 can be formed by the same formation method as that of the other O-M₁-O layers 5.

In the nonvolatile memory device 1 configured in this manner, when a voltage is applied to the metal electrode 8, oxygen atoms and M₁ atoms in the vicinity of each joining interface slightly move by the action of the electric field, so that the electrostatic potential distribution changes. Even when the movement of the oxygen atoms and the M₁ atoms is slight, the interface dipole (potential difference) is sensitive to the positions of the oxygen atoms and the M₁ atoms (charge distribution), so that the change in the electrostatic potential distribution is large. Further, when a reverse voltage is applied to the metal electrode 8, the oxygen atoms and the M₁ atoms move to the reverse direction, so that the electrostatic potential distribution returns to its original distribution.

That is, the nonvolatile memory device 1 can control the modulation of the interface dipole (potential difference) by voltage control on the metal electrode 8 and perform a nonvolatile information storage operation.

Note that the nonvolatile memory device 1 has the structure of an MOS (Metal-Oxide-Semiconductor) capacitor. When the capacity-voltage characteristic (C-V characteristic) is measured, a clockwise hysteresis characteristic is found in a case of the silicon semiconductor substrate 2 being a p-type semiconductor, and a counterclockwise hysteresis characteristic is found in a case of the silicon semiconductor substrate 2 being an n-type semiconductor. The hysteresis characteristics have a reverse relationship to hysteresis characteristics exhibited, by carrier capture in a general MOS capacitor formed of a metal electrode, an insulating film, and a semiconductor, such that a counterclockwise hysteresis characteristic is found in a case of a p-type semiconductor, and a clockwise hysteresis characteristic is found in a case of an n-type semiconductor.

### Second Embodiment

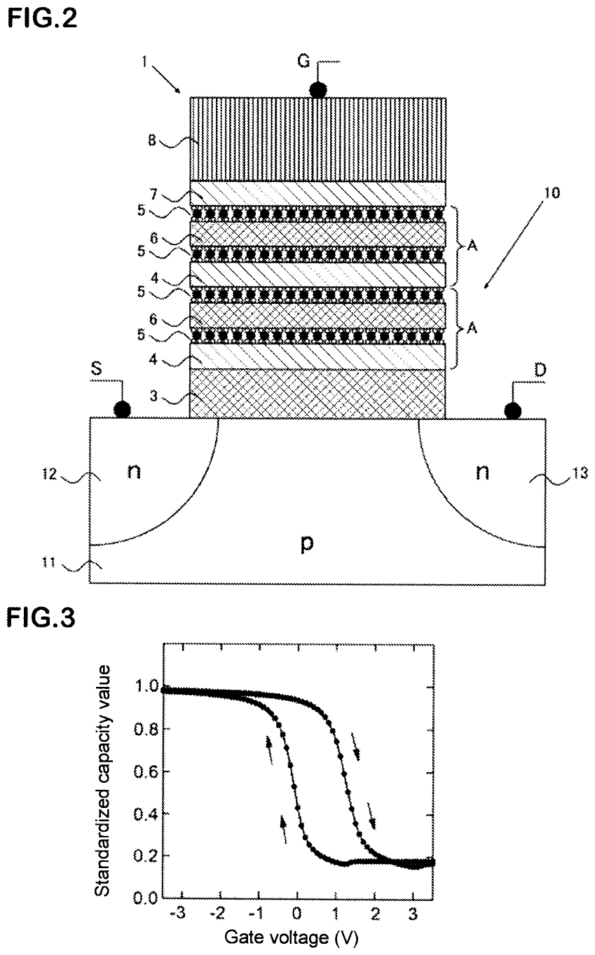

FIG. 2 is a sectional structural drawing according to the second embodiment of the nonvolatile memory device according to the present invention.

As illustrated in FIG. 2, a nonvolatile memory device 10 according to the second embodiment is configured such that the SiO₂ underlayer 3, the Al₂O₃ layers 4, the O-M₁-O layers 5, the SiO₂ layers 6, the Al₂O₃ metal electrode underlayer 7, and the metal electrode 8 in the nonvolatile memory device 1 according to the first embodiment are disposed on a silicon semiconductor substrate 11 instead of the silicon semiconductor substrate 2. The SiO₂ underlayer 3, the Al₂O₃ layers 4, the O-M₁-O layers 5, the SiO₂ layers 6, the Al₂O₃ metal electrode underlayer 7, and the metal electrode 8 can be formed similarly to the nonvolatile memory device 1.

The silicon semiconductor substrate 11 is a p-type (a first conductivity type), and n-type semiconductor regions (a second conductivity type) are formed in the substrate, so that the silicon semiconductor substrate 11 includes a semiconductor region of the p-type (the first conductivity type), and a source region 12 and a drain region 13 of the n-type (the second conductivity type) that are disposed to be distanced from each other in a state where the source region 12 and the drain region 13 are partially exposed from the surface of the silicon semiconductor substrate 11. Note that, differently from the embodiment illustrated herein, the silicon semiconductor substrate 11 may be the n-type (the first conductivity type), and in this case, the source region 12 and the drain region 13 of the p-type (the second conductivity type) are formed.

As the silicon semiconductor substrate 11, well-known p-type and n-type substrates can be used, and further, a formation method for the source region 12 and the drain region 13 to the silicon semiconductor substrate 11 may be a well-known formation method such as an ion implantation method, for example.

The nonvolatile memory device 10 configured in this manner has a three-terminal field-effect transistor structure with a source (S), a drain (D), and a gate (G). The operation principle of the nonvolatile memory device 10 is generally the same with a flash memory using threshold change by electric charge trapped by a gate laminated structure other than using threshold change based on the interface dipole modulation.

That is, the metal electrode 8 is used as a gate electrode, the strength or polarity of the interface dipole induced in the vicinity of the O-M₁-O layer 5 by an electrical signal applied to the gate electrode is changed to modulate the interface dipole to write information, and further, information is read out by using a change in a current value between the source region 12 and the drain region 13 when a change is given to a threshold (e.g., a flat band voltage) of the field-effect transistor structure based on the interface dipole thus modulated.

At this time, in the nonvolatile memory device 10, two types of insulating layers formed with different compositions are constituted by the Al₂O₃ layer 4 and the SiO₂ layer 6, and therefore, an excellent information retention characteristic is achieved.

Further, the constituent elements of the nonvolatile memory device 10 are general elements as silicon devices, and no special process technology is required, so that the nonvolatile memory device 10 can be easily manufactured by use of existing manufacturing facilities. In addition, by the manufacturing method using the ALD method in which deposition with a large area is performable at a time, the nonvolatile memory device 10 is mass-producible practically.

### EXAMPLES

### Examples 1 to 5

In accordance with the structure of the nonvolatile memory device 1 illustrated in FIG. 1, a nonvolatile memory device according to Example 1 was manufactured as follows. Note that, in the nonvolatile memory device according to Example 1, the formation of a repeating unit structure A of the Al₂O₃ layer 4, the O-M₁-O layer 5, the SiO₂ layer 6, and the O-M₁-O layer 5 is repeated six times, so that the number of the O-M₁-O layers 5, the interface dipole of which is modulable, is 12.

First, a p-type silicon semiconductor substrate having a thermally oxidized surface layer with a thickness of 5 nm was prepared and was used as the silicon semiconductor substrate 2 and the SiO₂ underlayer 3.

Subsequently, by a formation method by an ALD method using a single sheet processing ALD device, a sample was formed such that the formation of the repeating unit structure A constituted by the Al₂O₃ layer 4 having a thickness of 1.5 nm, a TiO₂ layer (the O-M₁-O layer 5) having a thickness of 0.14 nm, the SiO₂ layer 6 having a thickness of 1.5 nm, and a TiO₂ layer (the O-M₁-O layer 5) also having a thickness of 0.14 nm was repeated six times on the SiO₂ underlayer 3 to form 12 layers of the O-M₁-O layers 5, and the Al₂O₃ metal electrode underlayer 7 having a thickness of 3.5 nm was finally formed (a deposition step). Further, this sample was put in a horizontal external heating type furnace that can be evacuated, and a post heat treatment was performed for 30 minutes at a heating temperature of 350° C. in a mixed gas atmosphere of O₂/Ar (21 volume %) (a post heating step).

Subsequently, the metal electrode 8 was formed by vapor deposition of an iridium (Ir) layer having a thickness of 50 nm on the Al₂O₃ metal electrode underlayer 7 by an evaporation method using a stencil mask. Note that the vapor deposition of the iridium (Ir) layer was performed by use of an electron beam evaporation device.

Thus, the nonvolatile memory device according to Example 1 was manufactured.

Further, nonvolatile memory devices according to Examples 2 to 5 were manufactured similarly to Example 1 except that the heating temperature in the post heating step was changed from 350° C. to 250° C., 300° C., 400° C., and 450° C.

A nonvolatile memory device according to Example 2 was manufactured at the heating temperature of 250° C., a nonvolatile memory device according to Example 3 was manufactured at the heating temperature of 300° C., a nonvolatile memory device according to Example 4 was manufactured at the heating temperature of 400° C., and a nonvolatile memory device according to Example 5 was manufactured at the heating temperature of 450° C.

### Comparative Examples 1 to 5

By the formation method by the ALD method, a nonvolatile memory device according to Comparative Example 1 was manufactured similarly to Example 1 except that an HfO₂ layer having a thickness of 2.0 nm was formed instead of the Al₂O₃ layer 4 having a thickness of 1.5 nm, an SiO₂ layer having a thickness of 2.0 nm was formed instead of the SiO₂ layer 6 having a thickness of 1.5 nm, the formation of the repeating unit structure A was repeated three times to form six layers of the O-M₁-O layers 5, an HfO₂ layer having a thickness of 4.0 nm was formed instead of the Al₂O₃ metal electrode underlayer 7 having a thickness of 3.5 nm, the heating temperature in the post heating step was changed from 350° C. to 450° C., and a gold (Au) layer having a thickness of 50 nm was formed as the metal electrode 8 by a resistance heating vapor deposition device instead of the iridium (Ir) layer having a thickness of 50 nm.

Further, nonvolatile memory devices according to Comparative Examples 2 to 5 were manufactured similarly to Comparative Example 1 except that the heating temperature in the post heating step was changed from 450° C. to 250° C., 300° C., 350° C., and 400° C.

A nonvolatile memory device according to Comparative Example 2 was manufactured at the heating temperature of 250° C., a nonvolatile memory device according to Comparative Example 3 was manufactured at the heating temperature of 300° C., a nonvolatile memory device according to Comparative Example 4 was manufactured at the heating temperature of 350° C., and a nonvolatile memory device according to Comparative Example 5 was manufactured at the heating temperature of 400° C.

<Capacity-Voltage Characteristic (C-V Characteristic)>

By use of E4980A (LCR meter) made by Keysight Technologies, the nonvolatile memory devices according to Example 1 and Comparative Example 1 were subjected to the following measurement experiment of a capacity-voltage characteristic (a C-V characteristic).

First, a high frequency C-V measurement at 1 MHz was performed by a method (double sweep) in which a gate voltage swept in a negative direction from a positive voltage to a negative voltage was applied to the metal electrode 8, and sequentially, a gate voltage swept in a positive direction from the negative voltage to the positive voltage was applied to the metal electrode 8 again, and hereby, measurement results of the capacity-voltage characteristic (the C-V characteristic) were obtained.

Note that the gate voltage was set as follows: for the nonvolatile memory device according to Example 1, the negative voltage and the positive voltage were set to −11 V and +11 V, respectively; and for the nonvolatile memory device according to Comparative Example 1, the negative voltage and the positive voltage were set to lower voltages, i.e., −7 V and +7 V, respectively, because the nonvolatile memory device according to Comparative Example 1 had a total oxide film thickness thinner than that of the nonvolatile memory device according to Example 1.

With such a measurement method, it is possible to evaluate the magnitude of change in potential to be caused by the application of the positive and negative gate voltages.

FIG. 3 illustrates the measurement result of the capacity-voltage characteristic (the C-V characteristic) of the nonvolatile memory device according to Example 1.

As illustrated in FIG. 3, a clockwise hysteresis characteristic is observed in the nonvolatile memory device according to Example 1. The clockwise hysteresis characteristic means that changes in a MOS threshold voltage (e.g., a flat band voltage) by the interface dipole modulation occur.

Note that, in a case of the structure of a general MOS capacitor constituted by metal-insulator-semiconductor without depending on the interface dipole modulation, a counterclockwise hysteresis characteristic is obtained by hole injection from a p-type semiconductor.

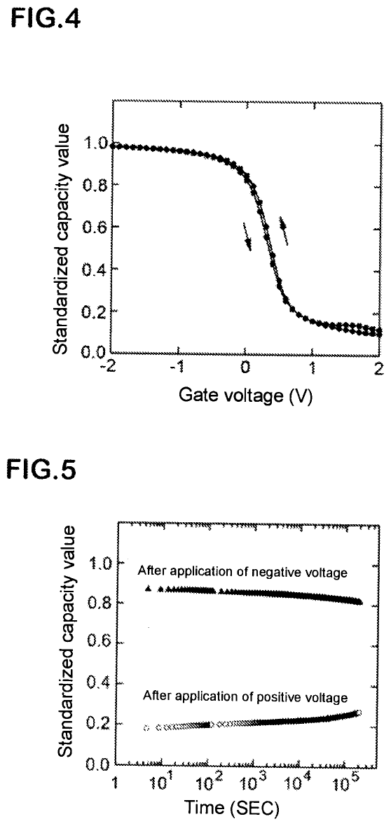

Subsequently, FIG. 4 illustrates the measurement result of the capacity-voltage characteristic (the C-V characteristic) of the nonvolatile memory device according to Comparative Example 1.

As illustrated in FIG. 4, in the nonvolatile memory device according to Comparative Example 1, a counterclockwise hysteresis characteristic is observed, and it is also found that the hysteresis voltage is small. From this, it is concluded that no interface dipole modulation occurs in the nonvolatile memory device according to Comparative Example 1.

<Information Retention Characteristic>

Subsequently, by use of the same device as the measurement experiment of the C-V characteristic, the nonvolatile memory devices according to Example 1 and Comparative Example 4 were subjected to measurement experiment of an information retention characteristic.

More specifically, after a gate voltage was applied by fixing the gate voltage to a positive voltage or a negative voltage, time dependency of a capacitance value was measured at around 0 V. Note that, at the time when the positive voltage was applied after the application of the negative voltage, low-frequency measurement at 5 kHz was performed under visible light irradiation. This voltage application condition is required to generate a sufficient electric field by forming an inverse state by generating minority carriers in the silicon semiconductor substrate 2.

Note that Comparative Example 4 relates to a sample obtained by performing the post heat treatment at a heating temperature of 350° C., similarly to Example 1.

FIG. 5 illustrates a measurement result of the information retention characteristic of the nonvolatile memory device according to Example 1.

As illustrated in FIG. 5, the nonvolatile memory device according to Example 1 has a sufficient information retention characteristic even after the lapse of 100,000 seconds.

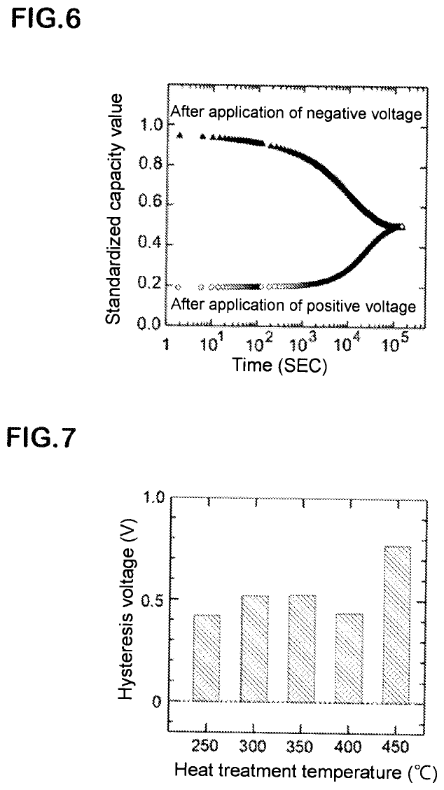

Subsequently, FIG. 6 illustrates a measurement result of the information retention characteristic of the nonvolatile memory device according to Comparative Example 4.

As illustrated in FIG. 6, the nonvolatile memory device according to Comparative Example 4 cannot retain information after the lapse of 100,000 seconds.

Thus, it is concluded that the nonvolatile memory device including Al₂O₃/SiO₂ as two different types of the insulating layers can retain information longer than the nonvolatile memory device including HfO₂/SiO₂ as two different types of the insulating layers.

<Heat Resistance>

Subsequently, the heat resistance is evaluated from the relationship between the hysteresis characteristic and the heat-treatment temperature characteristic in the nonvolatile memory device according to each of Examples 1 to 5 and Comparative Examples 1 to 5.

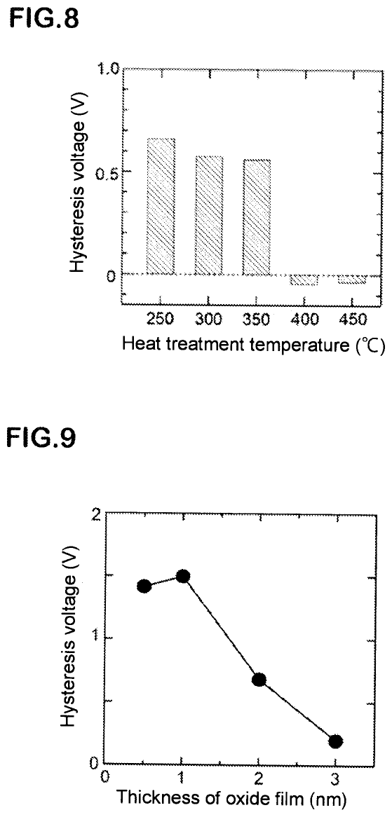

FIG. 7 is a view illustrating the relationship between the hysteresis characteristic and the heat-treatment temperature characteristic in the nonvolatile memory device according to each of Examples 1 to 5, and FIG. 8 is a view illustrating the relationship between the hysteresis characteristic and the heat-treatment temperature characteristic in the nonvolatile memory device according to each of Comparative Examples 1 to 5.

Note that the hysteresis voltage (V) on the vertical axis in each figure is the amount of change in flat band voltage estimated by the measurement experiment of the C-V characteristic. A positive value indicates that the clockwise hysteresis characteristic based on the interface dipole modulation is exhibited, and a negative value indicates that the counterclockwise hysteresis characteristic that does not depend on the interface dipole modulation is exhibited.

As illustrated in FIG. 7, the nonvolatile memory devices (subjected to the post heat treatment at 250° C., 300° C., 400° C., and 450° C., respectively) according to Examples 2 to 5 other than the nonvolatile memory device (subjected to the post heat treatment at 350° C.) according to Example 1 that has been examined earlier also have hysteresis voltages (V) of positive values and exhibit clockwise hysteresis characteristics based on the interface dipole modulation. Particularly, the nonvolatile memory device (the post heat treatment at 450° C.) according to Example 5 has a large hysteresis voltage and enables a high-performance memory operation.

In the meantime, as illustrated in FIG. 8, the nonvolatile memory device according to Comparative Example 5 other than the nonvolatile memory device (subjected to the post heat treatment at 450° C.) according to Comparative Example 1 that has been examined earlier has a hysteresis voltage (V) of a negative value, and it is concluded that no interface dipole modulation occurs.

Non Patent Document 2 also points out that the memory characteristic based on the interface dipole modulation is lost by heating after ALD deposition at a temperature of 400° C. or more in the post heating step, and the examination performed this time has also provided a similar result.

Thus, it is concluded that the nonvolatile memory device including Al₂O₃/SiO₂ as two different types of insulating layers is more excellent in heat resistance than the nonvolatile memory device including HfO₂/SiO₂ as two different types of insulating layers.

### Examples 6 to 9

Subsequently, preferable thicknesses of the Al₂O₃ layer 4 and the SiO₂ layer 6 are examined.

A nonvolatile memory device according to Example 6 was manufactured similarly to Example 1 except that the thickness of the Al₂O₃ layer 4 was changed from 1.5 nm to 0.5 nm, the thickness of the SiO₂ layer 6 was changed from 1.5 nm to 0.5 nm, the formation of the repeating unit structure A was repeated four times to form eight layers of the O-M₁-O layers 5, the heating temperature in the post heating step was changed from 350° C. to 400° C., and an aluminum (Al) layer having a thickness of 50 nm was formed as the metal electrode 8 by a resistance heating vapor deposition device instead of an iridium (Ir) layer having a thickness of 50 nm.

Further, nonvolatile memory devices according to Examples 7 to 9 were manufactured similarly to Example 6 except that the thicknesses of Al₂O₃ layer 4 and the SiO₂ layer 6 were changed to 1.0 nm, 2.0 nm, and 3.0 nm, respectively.

The nonvolatile memory device according to Example 7 was manufactured with the thickness of 1.0 nm, the nonvolatile memory device according to Example 8 was manufactured with the thickness of 2.0 nm, and the nonvolatile memory device according to Example 9 was manufactured with the thickness of 3.0 nm.

The Al₂O₃/SiO₂ thickness dependency of the hysteresis voltage is illustrated in FIG. 9 in which the vertical axis indicates the hysteresis voltage described in terms of the relationship between the hysteresis characteristic and the heat-treatment temperature characteristic, and the lateral axis indicates the thickness of the Al₂O₃ layer 4 and the SiO₂ layer 6.

As illustrated in FIG. 9, the hysteresis voltage of each of the nonvolatile memory devices according to Examples 6 to 9 has a positive value, and each of the nonvolatile memory devices according to Examples 6 to 9 has a clockwise hysteresis characteristic based on the interface dipole modulation. However, it is found that, as the thickness of each of the Al₂O₃ layer 4 and the SiO₂ layer 6 increases, the hysteresis voltage tends to decrease, and when the thickness is 3.0 nm, the hysteresis voltage is around 0.1 V.

Accordingly, from the viewpoint of obtaining a high-performance memory operation by the large hysteresis voltage, it is concluded that a preferable thickness for the Al₂O₃ layer 4 and the SiO₂ layer 6 is 2.0 nm or less.

### DESCRIPTION OF REFERENCE NUMERALS

1, 10 nonvolatile memory device
2, 11 silicon semiconductor substrate
3 SiO₂ underlayer
4 Al₂O₃ layer (first insulating layer)
5 O-M₁-O layer
6 SiO₂ layer (second insulating layer)
7 Al₂O₃ metal electrode underlayer
8 metal electrode
12 source region
13 drain region

1. A nonvolatile memory device having a laminated structure part including a plurality of first insulating layers and a plurality of second insulating layers formed with different compositions and disposed alternately, and an O-M₁-O layer of a 0.5 molecular layer to a 2.0 molecular layer formed by a chemical bond between a metal element M₁ and oxygen, and disposed on each joining interface between each of the first insulating layers and a corresponding one of the second insulating layers, the metal element M₁ being an element other than elements constituting the first insulating layers and the second insulating layers, and information being stored by modulating an interface dipole induced in the vicinity of the O-M₁-O layer due to external electrical stimulation,
wherein the first insulating layers are formed of aluminum oxide and the second insulating layers are formed of silicon oxide.

2. The nonvolatile memory device according to claim 1, wherein the first insulating layers have a thickness of 2 nm or less.

3. The nonvolatile memory device of claim 1, wherein the second insulating layers have a thickness of 2 nm or less.

4. The nonvolatile memory device according to claim 1, wherein the metal element M₁ is Ti.

5. The nonvolatile memory device according to claim 1, wherein the number of O-M₁-O layers with a modulable interface dipole is six or more.

6. The nonvolatile memory device according to claim 1, wherein a silicon semiconductor substrate and a silicon oxide underlayer laminated on a surface of the silicon semiconductor substrate are disposed and the first insulating layer of the laminated structure part is laminated on the silicon oxide underlayer.

7. The nonvolatile memory device according to claim 6, wherein an outermost surface of the laminated structure part is the second insulating layer with a surface of the first insulating layer side laminated on the silicone oxide underlayer being taken as a bottom surface, and an O-M₁-O layer, an aluminum oxide metal electrode underlayer, and a metal electrode are laminated on the outermost surface in this order.

8. The nonvolatile memory device according to claim 7, wherein the silicon semiconductor substrate includes a semiconductor region of a first conductive type, and a source region and a drain region of a second conductivity type, the source region and the drain region being disposed to be distanced from each other in a state where the source region and the drain region are partially exposed from a surface of the silicon semiconductor substrate and
strength or polarity of the interface dipole induced in the vicinity of the O-M₁-O layer is changed by an electrical signal applied to the metal electrode.

9. A manufacturing method for the nonvolatile memory device according to claim 1, comprising:
a deposition step of depositing and forming by an ALD method each constituent layer of a laminated structure part constituted by a first insulating layer, an O-M₁-O layer and a second insulating layer, and
a post heating step of heating the laminated structure part at a temperature of 250° C. or more after the deposition step.
